(19) United States
(12) Patent Application Publication
(10) Pub. No.: US 2021/0222325 A1
(43) Pub. Date: Jul. 22, 2021

(54) DIAMOND

(71) Applicant: Kanazawa Diamond Co., Ltd., Kanazawa-Shi (JP)

(72) Inventors: Norio TOKUDA, Kanazawa-Shi (JP); Masatsugu NAGAI, Kanazawa-Shi (JP)

(73) Assignee: Kanazawa Diamond Co., Ltd., Kanazawa-Shi (JP)

(21) Appl. No.: 17/186,176

(22) Filed: Feb. 26, 2021

Related U.S. Application Data
(63) Continuation of application No. PCT/JP2021/000090, filed on Jan. 5, 2021.

(30) Foreign Application Priority Data
Jan. 21, 2020 (JP) 2020-007770

(51) Int. Cl. C30B 29/04; C30B 25/02

(52) U.S. Cl. CPC C30B 29/04; C30B 25/02

(57) ABSTRACT

The present disclosure provides a diamond formed of a single crystal diamond consisting of carbon and tantalum with unavoidable impurities, and having a tantalum content in a range of 10¹⁸ to 10²¹ atoms/cm³, wherein the diamond has a black appearance.

### CROSS REFERENCE TO RELATED APPLICATION

This application is a continuation of International Patent Application No. PCT/JP2021/000090, having an international filing date of Jan. 5, 2021, which designated the United States, the entirety of which is incorporated herein by reference. Japanese Patent Application No.2020-007770 filed on Jan. 21, 2020 is also incorporated herein by reference in its entirety.

### BACKGROUND ART

The present disclosure relates to an artificial diamond having a black or similar appearance.

Since diamond has excellent properties such as a high hardness, a high light transmittance, and a wide bandgap, it is applied to tools and semiconductor devices, etc., but has also a high value of ornamental jewelry as so-called jewelry.

Among them, a black diamond having a black appearance has unique brilliance and is said to have a high jewelry value.

However, what is referred to as a conventional black diamond is a polycrystalline diamond utilizing light scattering or a diamond appearing black due to carbonization of a portion of the diamond by laser irradiation, radiation irradiation, thermal treatment, or the like, and it hardly reaches a level of a true black diamond.

JP-A-2018-39724 discloses a single-crystal CVD-diamond, wherein the single-crystal CVD-diamond is brown to black for a 1 mm thickness thereof and is not what is referred to as a true black diamond because it has two or more of diamond single crystal layers with different absorption coefficients of light at a 350 nm wavelength.

### DESCRIPTION OF EXEMPLARY EMBODIMENTS

An object of the disclosure is to provide a diamond formed of a single crystal and having a black or similar appearance.

In accordance with one of some embodiments, there is provided a diamond formed of a single crystal diamond consisting of carbon and tantalum with unavoidable impurities, and having a tantalum content in a range of 10¹⁸ to 10²¹ atoms/cm³, wherein the diamond has a black appearance.

Here, a single crystal diamond containing tantalum refers to a diamond in which tantalum (Ta) is doped in the diamond crystal. It is permissible to include light elements such as H, B, and N as unavoidable impurities.

Here, when tantalum is doped into the diamond crystal and impurities other than the unavoidable impurities are not included, the diamond exhibits a black appearance even after it is processed into various shapes as jewelry (ornamental jewelry), and therefore the diamond can be said to be a true black diamond. The diamond has a single-layer structure of single crystal diamond rather than the multi-layer structure. Further, in the diamond, graphite or graphene composed of SP2 carbon cannot be detected by Raman spectroscopy.

A tantalum content is set at a range of 10¹⁸ to 10²¹ atoms/cm³ so that when expressed in terms of the atomic ratio, Ta:C=1:10⁵ to 1:10², considering that the single crystal diamond has carbon atoms of about 10²³ atoms/cm³.

A method for doping tantalum in the diamond crystal includes, for example, a method for introducing tantalum by chemical reaction during the vapor phase synthesis of diamond.

Since the black diamond according to the disclosure has tantalum doped in the diamond crystal, it is different from a conventional diamond that is partially carbonized, and it exhibits a black appearance regardless of any shape of jewelry formed by subsequent processing.

In the synthesis of the diamond according to the disclosure, various methods can be employed if they enable tantalum to be incorporated into the crystal by chemical reaction when the diamond is synthesized from vapor phase. An example of synthesis by means of a hot filament CVD (HFCVD) method will be explained below where raw material gas is thermally decomposed by using high-temperature filaments in a deposition chamber for a diamond crystal to induce the deposition of diamond.

A hot filament CVD apparatus was used having a deposition chamber capable of heating by way of the hot filament and controlling reduced pressure, gas supply device for supplying raw material gas and carrier gas into the deposition chamber, and an exhaust pomp for exhausting the deposition chamber.

Tantalum or an alloy thereof, or tantalum carbide was used as the filament.

The melting point of tantalum is 3,017° C., and the melting point of tantalum carbide is 3,880° C.

Next, a production example of the black diamond according to the disclosure will be described.

A diamond single crystal (100) substrate with an off angle of 7.8 degrees was installed in the deposition chamber via a substrate holder or the like.

The deposition chamber was set at a pressure of 4 kPa, and methane (2 to 6 seem) was used as the raw material gas and hydrogen (100 seem) was used as the carrier gas.

It is noted that the methane gas concentration is preferably in the range of 1 to 10%.

As the hot filament, a multi-layer of hot filament was used that was composed of a first filament layer in which a plurality of filament wires were arranged on a plane at a predetermined interval at a predetermined height from the substrate, and a second filament layer in which a plurality of filament wires were similarly arranged on a plane at a predetermined distance from the first filament layer.

The number of the filament layers may be three or more.

In the present embodiment, filament wires having a diameter of 0.15 mm and disposed at an interval of 8 mm were used for the first layer and the second layer, and the distance between the first filament layer and the second filament layer was about 10 mm.

A heating temperature of the filament was set at 2,400 to about 3,000° C. The heat causes tantalum to be contained in the vapor phase, which contributes to diamond growth, and tantalum is doped into the diamond crystal.

The diamond thus obtained could be confirmed to be, a single crystal of diamond because it had a sharp peak with a peak half width of 2.8 cm⁻¹ at 1333 cm⁻¹ by Raman spectroscopy. Further, the diamond thus obtained has a single-layer structure of single crystal diamond, not a multi-layer structure.

Moreover, the appearance was pitch black, and the tantalum content was about 10¹⁸ atoms/cm³ according to the secondary ion mass spectrum.

A plasma CVD apparatus may be used instead of the hot filament CVD apparatus. In this plasma CVD apparatus, all or part of the material of the substrate holder on which the single crystal diamond substrate is placed is composed of tantalum, an alloy thereof, or tantalum carbide. As the source of tantalum, a solid other than the substrate holder, for example, a tantalum rod may be inserted into the plasma. In addition, gas containing tantalum may be supplied together with methane and hydrogen without using a solid tantalum.

When homoepitaxially growing diamond using the plasma CVD method, due to plasma and/or heat, tantalum is contained in the plasma and/or vapor phase that contributes to diamond growth. As a result, tantalum is doped into the homoepitaxial diamond CVD film.

### INDUSTRIAL APPLICABILITY

According to the disclosure, the diamond is obtained by vapor phase synthesis, and can be utilized as a diamond for ornamental jewelry, particularly such as a black diamond.

What is claimed is:

1. A diamond formed of a single crystal diamond consisting of carbon and tantalum with unavoidable impurities, and having a tantalum content in a range of 10¹⁸ to 10²¹ atoms/cm³, wherein the diamond has a black appearance.

2. The diamond according to claim 1, wherein an atomic ratio between the tantalum and the carbon is Ta:C=1:10⁵ to 1:10².

3. The diamond according to claim 1, wherein the diamond is used for ornamental jewelry.

4. The diamond according to claim 1, wherein the diamond has a single layer structure of the single crystal diamond.
